(19) United States
(12) Patent Application Publication
(10) Pub. No.: US 2026/0080131 A1
(43) Pub. Date: Mar. 19, 2026

(54) SYSTEM AND METHOD FOR ALL-ATOM COARSE GRAINED MOLECULAR DYNAMICS SIMULATIONS USING STOCHASTIC INTERPOLANTS

(71) Applicant: Massachusetts Institute of Technology, Cambridge, MA (US)

(72) Inventors: llan Mitnikov, Cambridge, MA (US); Allan dos Santos, Cambridge, MA (US); Joseph Jacobson, Cambridge, MA (US)

(73) Assignee: Massachusetts Institute of Technology, Cambridge, MA (US)

(21) Appl. No.: 19/330,452

(22) Filed: Sep. 16, 2025

Related U.S. Application Data
(60) Provisional application No. 63/695,181, filed on Sep. 16, 2024.

(51) Int. Cl. G06F 30/27

(52) U.S. Cl. CPC G06F 30/27

(57) ABSTRACT

A system and method for simulating all-atom molecular dynamics using a novel approach that leverages Special Orthogonal Group 3—equivariant stochastic interpolants. The method allows for efficient and accurate simulations across large time steps while maintaining detailed atomic representations. Unlike traditional methods, this approach is trained on the direct transfer of distributions between consecutive time steps, bypassing the need to predict the Boltzmann distribution and avoiding the complexities of force integration. The method is also designed to be transferable across different molecular systems, generalizing from training on a subset to a broader range. Additionally, the invention incorporates mirror interpolants to predict dynamics within the same time step, followed by sampling from a Boltzmann distribution and simulating time dynamics using Langevin dynamics. This approach provides a highly efficient and scalable solution for simulating all-atom molecular dynamics, applicable to a wide range of molecular systems.

### CROSS-REFERENCE TO RELATED APPLICATIONS

This application claims benefit to Provisional Application No. 63/695,181, filed Sep. 16, 2024, the contents of which are herein incorporated by reference.

### BACKGROUND OF THE INVENTION

### Field of Endeavor

The present invention relates to machine learning systems and methods for Molecular Dynamics, and more particularly, to a system and method for all-atom modelling and simulation of molecular dynamics using stochastic interpolants.

### Background of Related Art

Proteins are complex biological macromolecules made of amino acid chains that are essential for nearly every process within organisms. The specific shape of a protein, determined by the sequencing of amino acids therein, dictates their function. Proteins provide invaluable insights into fundamental cellular processes which are used in disease research and diagnostics, drug discovery and development, and cellular and molecular studies, among other areas of scientific endeavor.

Molecular Dynamics Simulation is a computational method that utilizes physical laws, or physics-based principles, to model the movement of systems, such as atoms and molecules over time, providing a dynamic view of biological and chemical systems, such as proteins. Specifically, a system's evolution over time is determined by solving Newton's equations of motion to calculate forces on each component of the system, such as atoms, particles, etc., revealing how the system evolves. Typically, Newton's equations are integrated over discrete time steps, often using the velocity Verlet algorithm, with small time steps, typically a femtosecond, to ensure stability. For protein simulation, sampling physically accurate molecular potentials requires larger time steps, on the order of micro- or milliseconds, resulting in many iterations of Molecular Dynamics, making the process computationally expensive.

Typical approaches to modeling Molecular Dynamics in proteins, both classical force field based and machine learning approaches, rely on approximations, such as coarse-graining, and metadynamics, to reduce computational expense, but these approximations limit the ability to simulate the full complexity of protein dynamics at an all-atom level. Additionally, these approaches typically sample from a prior distribution while conditioning on an initial configuration. These approaches rely on transforming the prior distribution, such as a Gaussian Distribution, via one or more Stochastic Differential Equations, and/or Ordinary Differential Equations, where the prior is often far from the true distribution. In addition to the above limitations, these models are system specific, lacking the ability to generalize, and therefore needing to be retrained for each system, or protein, that is being evaluated.

As can be seen, there is a need for a system and method for all-atom coarse-grained molecular dynamics simulations using stochastic interpolants configured to simulate molecular dynamics at the all-atom level across multiple molecular systems, enable direct time-step transfer between consecutive simulation steps using stochastic interpolants, and ensure that the predicted dynamics respect physical symmetries, being both translation-invariant and rotation-equivariant, offering a highly efficient, accurate and scalable solution for simulating all-atom molecular dynamics across proteins, with particular applications in molecular and materials science.

### SUMMARY OF THE INVENTION

This invention introduces a system, method, and non-transitory computer-readable medium for simulating the dynamics of all-atom molecular systems using SO(3)-equivariant stochastic interpolants. The method facilitates the direct transfer of distributions between consecutive time steps, maintaining detailed atomic representations. Unlike traditional approaches that require Boltzmann distribution predictions or force integrations, this method simplifies training and enhances performance by focusing on a transfer operator.

Broadly, embodiments of the present invention provide a computer-implemented method, computational system, and non-transitory computer-readable medium configured to perform the following: receive an initial molecular conformation having at least: an encoded sequence of residue labels, and an encoded representation of a plurality of geometric features; generate, using a conditioner network, a conditioned representation of the initial molecular conformation; iteratively determine a next molecular conformation, comprising: sampling a noise perturbation; compute, using a plurality of drift networks, a plurality of drift components using the initial molecular configuration, the conditioned representation, and a latent time; compute, using a plurality of noise networks, a plurality of noise components using the initial molecular configuration, the conditioned representation, and the latent time; calculate, using an update equation, an update step, wherein the plurality of drift components, the plurality of noise components, and the noise perturbation are inputs to the update equation; calculate the next molecular conformation using the initial molecular conformation and the update step; repeat (c), until a target molecular conformation is reached; and output, to the display device the target molecular conformation.

### BRIEF DESCRIPTION OF THE DRAWINGS

FIG. 1 is a schematic architecture of a transport operator for use in molecular dynamic simulation, according to aspects of the present invention;

FIG. 2 is a schematic diagram of a deep neural network employed in the transport operator, according to aspects of the present invention;

FIG. 3 is a schematic diagram of a self-interaction layer of the deep neural network, according to aspects of the present invention;

FIG. 4 is a schematic diagram of a spatial convolution layer of the deep neural network, according to aspects of the present invention; and

FIG. 5 is a flow diagram of a method performed by the transport operator for use in molecular dynamics simulation, according to aspects of the present invention.

### DETAILED DESCRIPTION OF THE INVENTION

The following detailed description is of the best currently contemplated modes of carrying out exemplary embodiments of the invention. The description is not to be taken in a limiting sense but is made merely for the purpose of illustrating the general principles of the invention, since the scope of the invention is best defined by the appended claims.

Simulations by mapping the conformational dynamics of a protein, or proteins, to elucidate their functional mechanisms is critical to scientific endeavors related to protein dynamics and interactions. While Molecular Dynamics (MD) simulation enables detailed time evolution of protein motion, its computational toll hinders its use in practice. To address this challenge, multiple deep learning models for reproducing and accelerating MD have been proposed drawing on transport-based generative methods. However, existing work focuses on generation through transport of samples from prior distributions, that can often be distant from the data manifold. The recently proposed framework of stochastic interpolants, instead, enables transport between arbitrary distribution endpoints.

### Overview of Stochastic Interpolants

Generative models are a class of machine learning models that can create new data instances that are similar to the data on which they were trained. A prominent approach in generative modeling is to define a continuous-time process that transforms a simple, easy-to-sample distribution (like a Gaussian) into a complex, target data distribution. This framework has led to the development of powerful models like normalizing flows, which use invertible mappings, and diffusion models, which use stochastic differential equations to gradually denoise data. The background of generative models, particularly those based on the dynamic transport of measure, laid the groundwork for a more unified approach.

Stochastic interpolants (SIs) emerged from this background as a unifying framework for flows and diffusions. They define a continuous-time stochastic process that can transform between any two arbitrary probability distributions, connecting a simple starting distribution to the target data distribution in a controlled way. A key innovation of SIs is the use of an interpolant function that can be either deterministic or stochastic, allowing for a flexible trade-off between the two. By framing the generative process as a dynamic system, SIs can be learned by solving simple quadratic regression problems to estimate the necessary drift coefficients for the underlying differential equations. This approach provides a robust and flexible method for training generative models, including recent advancements like Latent Stochastic Interpolants, which operate in a learned latent space to improve efficiency.

Stochastic Interpolants come in two forms, one-sided interpolants, and two-sided interpolants. One-sided interpolants transport samples from a prior distribution X₀, typically a Gaussian, to a target distribution X₁, belonging to an arbitrary distribution function ρ₁, using latent variables Z, belonging to a Gaussian, through a stochastic process X^{t}=J(τ,X₁)+α(τ)Z. In the one-sided process, τ ∈ [0,1] is the time parameterization and J is the interpolant function, which satisfies the boundary conditions, J(0, X₁)=0 and J(1, X₁)=X₁. Additionally, the noise schedule α(τ) satisfies α(0)=1 and α(1)=0. In contrast, two-sided interpolants enable learning of transport from X₀, belonging to a first arbitrary distribution ρ₀, to X₁, belonging to a second arbitrary distribution ρ₁, through the stochastic process X^{t}=I(τ, X₀, X₁)+γ(τ)Z, where I is the interpolant function, and γ is the noise schedule. The boundary conditions for two-sided interpolants include I(0, X₀, X₁)=X₀, I(1, X₀, X₁)=X₁, and γ(0)=γ(1)=0. A special class of two-sided interpolants, mirror interpolants, exhibit the same stochastic process, i.e.

$${X}_{t}^{Mir} = J ( τ , {X}_{1} ) + α ( τ ) Z ,$$

and modified boundary conditions, J(0, X₁)=X₁, J(1, X₁)=X₁, and α(0)=α(1)=0.

The probability of a stochastic interpolant satisfying the transport equation is given by ∂_{τ}p(τ,X)+V̅ ·(b(τ,X)p(τ,X))=0, where b(τ,X)=E[∂_{τ}I(τ, X₀, X₁)+∂_{τ}γ(τ)Z|X_{τ}=X] is the expected velocity and the boundary conditions p(0,X)=p₀ and p(1,X)=p₁. Additionally, a noise term η(τ, X)=E [Z|X_{τ}=X]. In practice b and f are not known for arbitrary distributions p₀ and p₁, but are needed for sampling and returning a next state in a Stochastic Interpolant.

Broadly, an embodiment of the present invention provides a system and method for simulating the dynamics of all-atom molecular systems using Special Orthogonal Group 3, SO3, equivariant stochastic interpolants. The system and method of the present invention utilize machine learning models, such as Euclidean equivariant neural networks, within the generative framework of Stochastic Interpolants for directly transporting 3D all-atom proteins between simulation time steps. The present invention trains one or more machine learning models, on molecular modeling data, to parameterize one or more generative models, such as a Stochastic Interpolant. Additionally, once trained, the one or more machine learning models are utilized to sample the parameters for the one or more generative models, in order to iteratively transport a molecular conformation from a source representation to a target representation. The method facilitates the direct transfer of distributions between consecutive time steps, maintaining detailed atomic representations. Unlike traditional approaches that require Boltzmann distribution predictions or force integrations, this method simplifies training and enhances performance by focusing on a transfer operator.

The present invention provides numerous advantages including, but not limited to: enabling simulations at the all-atom level, ensuring that atomic details are preserved while simulating the molecular dynamics across large time steps; enabling direct time-step transfer between consecutive steps using stochastic interpolants, improving the efficiency and accuracy of all-atom molecular dynamics simulations; enabling a transferable and generalizable model designed to be transferable across different molecular systems, allowing for generalization from training on a subset of systems to a broader range; enabling sampling from a Boltzmann distribution and simulation of time dynamics using Langevin dynamics through the use of mirror interpolants to predict system dynamics within the same time step; and ensuring that the predicted dynamics, of a system model, respect physical symmetries, being both translation-invariant and rotation-equivariant, using the SO3 equivariant framework described hereinafter.

### Architectural Overview

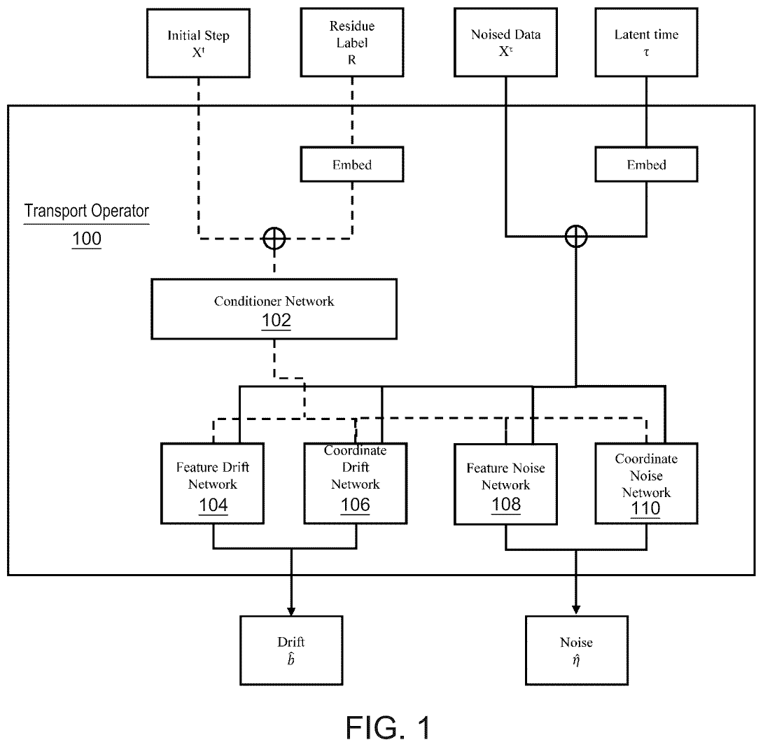

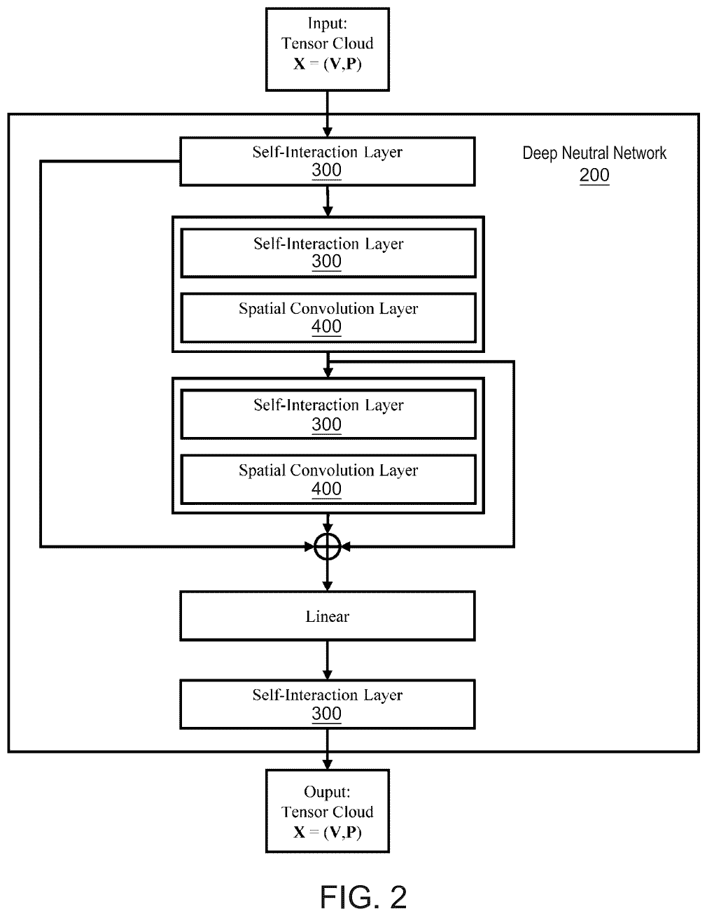

Referring now to the Figures, aspects of the present invention are illustrated. Specifically, FIG. 1 illustrates a schematic diagram of a Transport Operator 100 configured to learn one or more parameters of a generative model using training data, and/or to sample the one or more parameters for use in the time evolution of one or more molecular structures. Functionality of Transport Operator 100 is described with respect to FIG. 1, while the architectural components such as, but not limited to a conditioner network 102, a plurality of drift networks 104-106, and a plurality of noise networks 108-110, are described further with respect to FIG. 2-4.

Transport operator 100 takes an input model(s) of a molecular structure, such as model(s) of a protein molecule, for use in both learning and time evolution operations. In embodiments, model(s) is represented by

$$X = {[ ( {R}_{i} , {V}_{i} , {P}_{i} ) ]}_{i = 1}^{N} ,$$

as a list of labels and geometric features positioned in 3-dimension, where Rᵢ is a residue label, Vᵢ is a tensor cloud of irreducible representations in Special Orthogonal Group 3 (SO3), and Pᵢ is a 3-dimensional coordinate, i.e. Pᵢ ϵ [symbol] ³. In embodiments, Rᵢ is one of the 20 common protein residue labels, i.e. [Alanine, Arginine, Asparagine, Aspartic acid, Cysteine, Glutamic acid, Glutamine, Glycine, Histidine, Isoleucine, Leucine, Lysine, Methionine, Phenylalanine, Proline, Serine, Threonine, Tryptophan, Tyrosine, Valine]. In embodiments, the tensor cloud of representations V are composed of lₘₐₓ tensors where each V^{l} for 1 ∈ [0, lₘₐₓ] represents geometric features of size [H, 2l+1] for some hidden dimensionality hyperparameter, H.

Model(s) is encoded using the Atom-14 representation, adapted to featurization in SO3. In embodiments, encoding in this manner sets position Pᵢ, for each residue Rᵢ, to the 3-dimensional coordinate of the Rᵢ's alpha carbon, C_{α}. Once Pᵢ is set, relative vectors from C to all other atoms in Rᵢ are input as geometric features in V^{l=1}∈ [symbol] V^{l=1} encodes the relative 3D vector from the C to all other heavy atoms in the residue, following a canonical ordering. In embodiments, for residues with fewer than 13 non-Cα heavy atoms, atom vectors can be padded, such as by zero-padding. Additionally, the Rᵢ is tokenized and embedded as a scalar feature V^{l=0}. In embodiments, Rᵢ is tokenized and embedded as a one-hot feature vector but is not so limited. Advantageously, modelling features utilizing this encoding allows for direct representation of all heavy atoms in 3-dimensions, while maintaining coarse-grained representation anchored on C.

Transport Operator 100 includes a plurality of networks, such as conditioner network 102, feature drift network 104, coordinate drift network 106, feature noise network 108, and/or coordinate noise network 110. In embodiments, each of the plurality of networks is a deep network 200, as illustrated in FIG. 2. In embodiments, each deep network 200, and/or one or more components thereof is implemented as a neural network, which can be constructed using various architectures, including but not limited to Convolutional Neural Networks (CNNs), Euclidean Equivariant neural networks, Transformers, invariant and equivariant message passing neural networks, tensor field networks, and fully connected layers. This flexibility allows the system to be tailored to the specific needs of the molecular dynamics simulation.

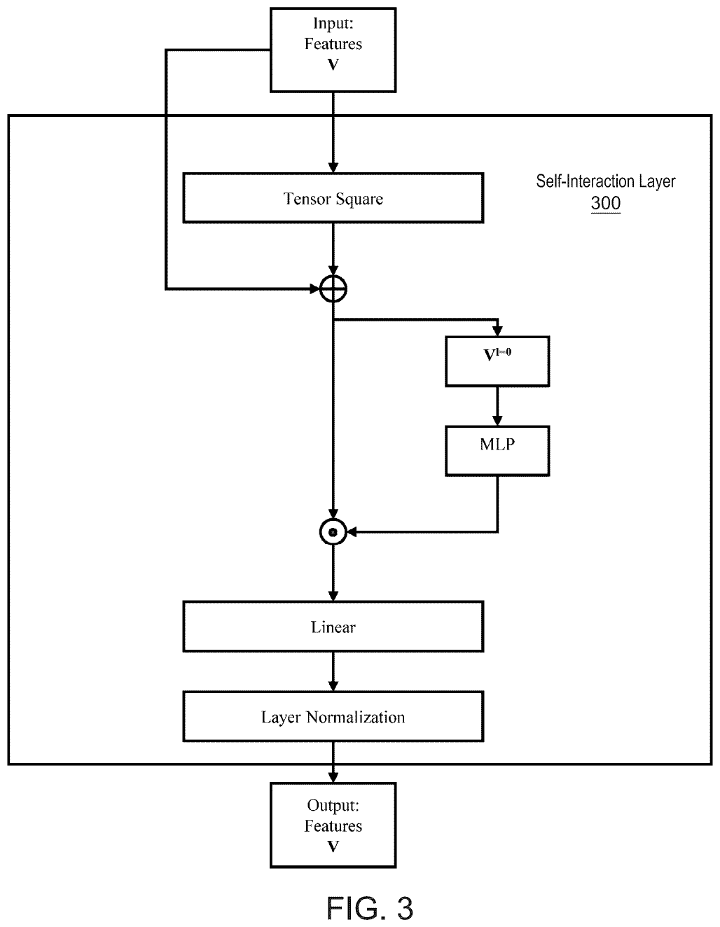

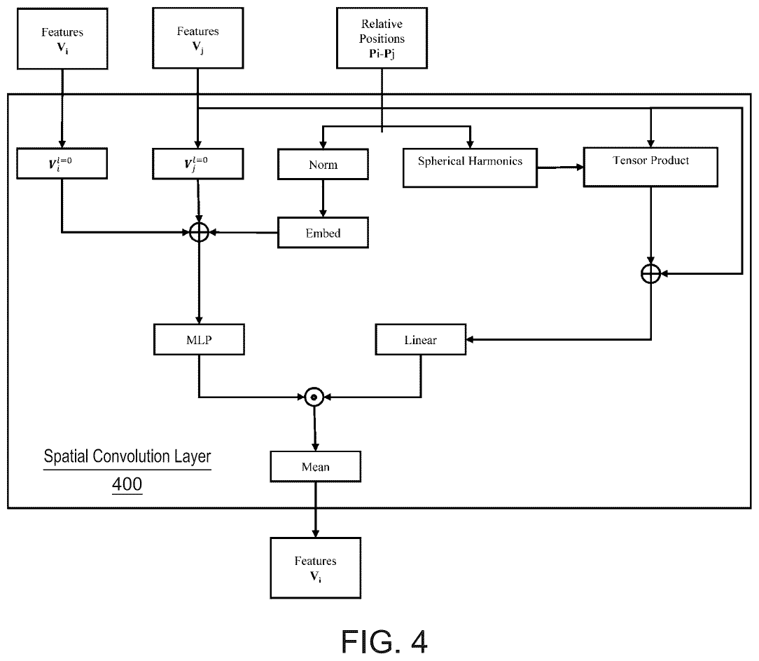

In embodiments, each of the plurality of networks, as a deep network includes a number, L, of stacked blocks of self-interaction layers, as illustrated in FIG. 3, and spatial convolution layers, as illustrated in FIG. 4. In exemplary embodiments, L is a design parameter that can be adjusted and modified depending on the specific requirements of the simulation. This adaptability ensures that the transport operator can be customized to optimize performance across various molecular dynamics scenarios. In exemplary embodiments, L=6 for the conditioner network 102 and L=4 for networks 104-110.

In operation each of the plurality of networks as a deep network receives as input the model X, or a subset thereof, as a tensor cloud, and returns a tensor cloud representation for further use by transport operator 100. Specifically, each of the plurality of networks operates according to algorithm 1, below:

```
            ALGORITHM 1: DEEP NETWORK
            Require: Tensor Cloud X = (P, V^{0:lmax})
```

| | |
|---|---|
| 1: | H⁰ ← Self-Interaction(X) |
| 2: | for 1 in [0, L] do |
| 3: | H¹⁺¹ ← Self-Interaction(H¹) |
| 4: | H¹⁺¹ ← SpatialConvolutoin(H^{l+1}) |
| 5: | H¹⁺¹ ← LayerNorm(H^{l+1} + H¹) |
| 6: | ${H}^{agg} ← Linear ( {⊕}_{l = 0}^{L - 1} {H}^{l} )$ |
| 7: | H^{out} ← Self-Interaction(H^{agg}) |
| 8: | return H^{out} |

As can be seen, the plurality of neural networks operate to receive a tensor cloud, and output a new tensor cloud by iterating through stacked layers of Self-Interaction layers, SpatialConvolution layers, and Normalization layers. Briefly, and described in more detail with respect to FIGS. 3-4, respectively, the Self-Interaction layer updates geometric features V^{l} from coordinates, while the Spatial convolution layer shares information between neighbors, based on Tensor Field networks, and the LayerNorm normalizes any inputs across the features for each data point within the layer.

Referring now to the Self-Interaction Layer 300, FIG. 3 illustrates a schematic diagram of a Self-Interaction layer 300 of the plurality of deep neural network of FIG. 2. Self-Interaction layer 300 is configured to update geometric features independently, mixing V^{l} of different degrees into new features through a Tensor Square operation. In embodiments, Self-interaction layer 300 models the internal interactions of atoms within each residue. Self-interaction layer 300 performs a transformation updating the feature vectors

$${V}_{i}^{0 : lmax}$$

centered at the same residue Rᵢ. Specifically, the Self-Interaction layer 300 combines feature vectors V^{l} of varying degrees 1 by employing tensor products of the features with themselves.

More specifically, self-interaction layer 300 operates according to the algorithm 2, below:

ALGORITHM 2: Self-Interaction

Require: Tensor Cloud (P,V)
1:V ← V ⊗(V)^{⊗2}
2: V ← MultiLayer Perceptron (V^{l=0}) * V
3: V ← Linear(V)
4: Return (P,V)

Referring now to the Spatial Convolution Layer 400, FIG. 4 illustrates a schematic diagram of the Spatial Convolution Layer 400 of the plurality deep neural networks of FIG. 2. Spatial Convolution Layer 400 is configured to update feature representations by aggregating the tensor product of neighboring messages with the spherical harmonics embedding of the relative 3D vector between the positions of those neighbors. In embodiments, Spatial Convolution Layer 400 captures interactions of residues that are close in three-dimensional space, by updating representations and positions through message passing within k-nearest spatial neighbors. Message representations incorporate SO(3) signals from the vector difference between neighbor coordinates, and messages are aggregated with a permutation-invariant means. After aggregation, a linearl transformation of the vector representations is performed resulting in an update for the coordinates.

More specifically, spatial convolution layer 500 operates according to the algorithm 3, below:

ALGORITHM 3: Spatial Convolution
Require: Tensor Cloud (V, P)
Require: Output Node Index i

| | |
|---|---|
| 1: | (P′, V′)_{1:k} + kNN (Pᵢ, P_{1:N}) |
| 2: | R_{1:k←Embed (∥P′}_{_{1:k}}_{-P}_{ᵢ}_{∥}_{₂}₎ |
| 3: | φ_{1:k ←Spherical Harmonics (∥P′}_{_{1:k}}_{-P}_{ᵢ}_{∥}_{₂}₎ |
| 4: | ${V}_{1 : k ← MLP ( {R}_{k} ⊕ {V}_{1 : k}^{l = 0} ⊕ {V}^{l = 0} ) * Linear ( {V}_{1 : k}^{′} ⊗ {ϕ}_{1 : k} ) Spherical Harmonics ( {‖ {P}_{1 : k}^{′} - {P}_{i} ‖}_{2} )}^{′}$ |
| 5: | $V ← Linear ( V + \frac{1}{k} ( {\sum }_{k} {V}_{k}^{′} ) )$ |
| 6: | Return: (V, P) |

### Transport Operator 100—Training

Returning back to Transport operator 100, with general architectural components and algorithms disclosed, specific operational aspects, training, and sampling, are now disclosed. Specifically, Transport operator 100 is designed to predict one or more feature drift components, \hat{b}, and one or more noise components, \hat{η}. In embodiments, the one or more feature drift components are drifts associated with components of the tensor cloud X, such as geometric features of Vᵢ and coordinates Pᵢ, and are given as \hat{b}=( [symbol] , [symbol] ). In embodiments, the one or more noise drift components are drifts associated with components of the tensor cloud X, such as a geometric features of Vᵢ and coordinate Pᵢ, and are given as \hat{η}=( [symbol] , [symbol] ). Transport Operator 100 is trained to predict \hat{b} and \hat{η}conditioned on sequence R, a source structure X^{t}, a latent transport structure X_{τ}^{t}, and a latent time τ, utilizing the stacked deep neural network architecture, described above.

Specifically, Transport operator 100 is trained according to algorithm 4, below:

ALGORITHM 4: Training
Require: Sequence R
$Require : Trajectory {Data [ {X}^{t} ]}_{t = 1}^{T}$
Require: Interpolant parameters I_{τ}, γ(t)
Require: Transport Operator (Networks [symbol] , [symbol] , [symbol] , [symbol] , and f_{cond})

| | |
|---|---|
| 1: | t~U(1, T − 1) |
| 2: | τ~U(0, 1) |
| 3: | Z^{τ}~N(0, 1)00 |
| 4: | \tilde{X}^{t} ← f_{cond}(R, X^{t}) |
| 5: | ${X}_{τ}^{t} = ( 1 - τ ) \cdot {X}^{t} + τ \cdot {X}^{t + 1} + γ ( t ) {Z}^{τ}$ |
| 6: | $\hat{η} ← ( {\hat{η}}_{V} ( {\tilde{X}}^{t} , {X}_{τ}^{t} , τ ) , {\hat{η}}_{P} ( {\tilde{X}}^{t} , {X}_{τ}^{t} , τ ) )$ |
| 7: | $\hat{b} ← ( {\hat{b}}_{V} ( {\tilde{X}}^{t} , {X}_{τ}^{t} , τ ) , {\hat{b}}_{P} ( {\tilde{X}}^{t} , {X}_{τ}^{t} , τ ) )$ |
| 8: | GRADIENT STEP |
| 9: | $- ∇ ( \frac{1}{2} ‖ \hat{b} ‖ - \hat{b} \cdot ( {\partial }_{τ} {I}_{τ} ( {X}^{t} , {X}^{t + 1} ) + \dot{γ} ( τ ) \cdot {Z}^{τ} ) + \frac{1}{2} ‖ \hat{η} ‖ - \hat{η} \cdot {Z}^{τ} )$ |

Broadly, during training a generative model, such as a two-sided stochastic interpolant framework learns a time evolution operator from trajectory data [X^{t}]ₜ₌₁^{T}. Given a source time step X^{t} and its consecutive target step X^{t+1}, the distribution boundaries of the interpolant are defined as as ρ0=ρ(X^{t}) and ρ1=ρ(X^{t+1}|X^{t}). The conditional nature of the target distribution requires that predictions for drift b and noise 14 are explicitly conditioned on the source step X.

Specifically, during training Transport operator 100 receives a model of a molecular structure X, as defined above, having a sequence R of residue structures, and trajectory data X^{t}. In addition to the molecular structure Interpolant parameters such as an interpolant function, I_{τ}, and noise schedule, γ(t), are provided. In embodiments, the interpolant is a generative model, such as a stochastic interpolant. In embodiments, the stochastic interpolant is a two-sided stochastic interpolant. Additionally, the interpolant function can be given by I(τ, X₀, X₁)=(1−τ)·X₀+τX₁ and the noise schedule is given by γ(τ)=σ·τ·(1−τ). In exemplary embodiments, a special class of two-sided interpolants are utilized, such as mirror interpolants, as described above. It is understood that while embodiments of the present invention utilize interpolants, such as two-sided stochastic interpolants, the invention can be generalized to utilize any function, model, etc., configured to transform a first distribution to a second distribution.

In embodiments, the interpolant function and noise schedule are configurable, and limited only by the requirements of stochastic interpolants, as described above. Advantageously, Stochastic Interpolants enable smoothing of the data manifold by convolution with small Gaussian perturbations, leading to a latent representation that is robust to noise, allowing for larger integration steps. The smoother manifold helps overcome local energy barriers and navigate the broader conformational landscape more efficiently, making it possible to simulate molecular dynamics on extended timescales without losing stability.

During training conditioner network 102, f_{cond}, utilizes the sequence R, and the previous trajectory data, X^{t}, to create a first hidden representation, \tilde{X}^{t}, and the interpolant generates a latent transport structure,

$${X}_{τ}^{t} ,$$

utilizing the previous trajectory data, X^{t}, a target trajectory data, X^{t+1}, the noise schedule, γ(τ), and a noise perturbation Z, drawn from a distribution, such as a normal distribution.

The output of conditioner network 102, hidden representation \tilde{X}^{t}, and the output of the interpolant,

$${X}_{τ}^{t} ,$$

along with the latent time, r, are provided to feature drift network 104, coordinate drift network 106, feature noise network 108, and/or coordinate noise network 110, and each of the networks predicts one of: [symbol] , [symbol] , [symbol] , [symbol] , respectively. Once noise and drifts are calculated, the gradient step attempts to minimize the loss to guide Transport operator 100 to the most accurate configuration thereby allowing Transport operator 100, during sampling, to provide accurate predictions for the one or more feature drift components and the one or more noise components.

It is understood that, while embodiments of the training algorithm are shown above, modifications to the training algorithm contemplated as being within the scope of the invention. For example, one or more of the prediction networks, or their functionality can be altered, or removed. Additionally, the gradient step may be altered, to accommodate minimization of loss based on the selection of networks. It is understood that the training process is iterative, such that outputs from the initial step are fed back into the training algorithm of Transport operator 100, and the gradient step, attempting to minimize loss, occurs at each step until a threshold optimization has been achieved.

Advantageously, training of Transport operator 100 on trajectory data X^{t}, utilizing a two-sided stochastic interpolant, overcomes disadvantages associated with prior systems that leverage Gaussian priors, which often lie far from the true data distribution. More specifically, the two-sided stochastic interpolant leverages the configuration proximity of consecutive timesteps and enables a transport that stays close to physical states, thereby allowing larger timesteps in MD simulations, and reducing computations needed therein.

### Transport Operator 100—Sampling

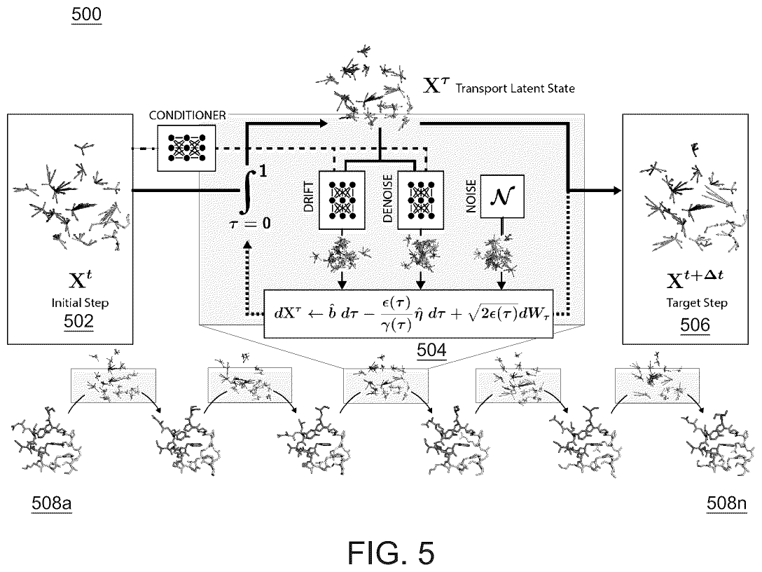

FIG. 5 provides a visual representation of a sampling methodology 500 provided using Transport operator 100. In embodiments, Transport operator 100 once trained, as described above, predict one or more feature drift components, \hat{b}, and one or more noise components, \hat{η}. In embodiments, the transport operator utilizes the predictions for sampling a next state using one or more differential equations. In embodiments, the one or more differential equations can be an Ordinary Differential Equation (ODE), and/or a Stochastic Differential Equation (SDE). In embodiments, the results of the sampling methodology are one or more states of an input model from a first state to a target state. In embodiments, the input model is a molecular model, such that the results of the sampling methodology simulate molecular dynamics.

In embodiments, the sampling methodology operates according to algorithm 5, below:

ALGORITHM 5: Sampling
Require: Sequence R
Require: Start Step X^{t}
Require: Interpolant parameters ϵ(τ), γ(t)
Require: Transport Operator (Networks [symbol] , [symbol] , [symbol] , [symbol] , and f_{cond})
Require: Integration Timestep dτ

| | |
|---|---|
| 1: | ${X}_{τ = 0}^{t} ← {X}^{t}$ |
| 2: | \tilde{X}^{t} ← f_{cond}(R, X^{t}) |
| 3: | for (τ ← 0; τ < 1; τ ← τ + dτ) do |
| 4: | Z^{τ}~N(0, I) |
| 5: | $\hat{η} ← ( {\hat{η}}_{V} ( {\tilde{X}}^{t} , {X}_{τ}^{t} , τ ) , {\hat{η}}_{P} ( {\tilde{X}}^{t} , {X}_{τ}^{t} , τ ) )$ |
| 6: | $\hat{b} ← ( {\hat{b}}_{V} ( {\tilde{X}}^{t} , {X}_{τ}^{t} , τ ) , {\hat{b}}_{P} ( {\tilde{X}}^{t} , {X}_{τ}^{t} , τ ) )$ |
| 7: | ${dX}^{τ} ← ( \hat{b} - \frac{ϵ ( τ )}{γ ( τ )} \hat{η} ) d τ + \sqrt{2 ϵ ( τ )} {Z}^{τ}$ |
| 8: | ${X}_{τ + d τ}^{t} ← {X}_{τ}^{t} + {dX}_{τ}^{t}$ |
| 9: | $return {X}_{τ = 1}^{𝔱}$ |

Broadly, during sampling simulation of all-atom protein dynamics, as depicted in FIG. 5. In this context, X^{t} represents a 3D all-atom protein conformation at time t, which can be an initial state 502, which is provided as input to transport operator 100. X^{t} is framed as the source distribution, and set X_{τ=0}=X^{t}. An iterative process governed by the integration of one or more differential equations, 504, from τ=0 to τ=1. Sampling in this manner produces a sample X_{τ=1}, which follows the distribution X_{τ=1}˜ρ₁, generating a next step in the simulation Xₜ₊₁, 506.

Specifically, with reference to FIG. 5 an initial state 502 is provided to conditioner network 102, f_{cond}, which utilizes the sequence R, and the previous trajectory data, X^{t}, to create a first hidden representation, \tilde{X}^{t}.

Once the hidden representation is created, the transport operator 100 loops predicting noise, \tilde{η}, and drift, \hat{b}, using the previous trajectory data, X^{t}, the first hidden representation, \tilde{X}^{t}, and the latent time, τ, in each of the drift networks 104-106 and noise networks 108-110. For computational efficiency, hidden representation \tilde{X}^{t} is made independent of τ, and only drift networks 104-106 and noise networks 108-110 are used in the integration loop.

One or more differential equations, such as an ODE and/or SDE, are utilized in an integration process 504, outlined in line 7 above, which utilizes noise and drift predictions, along with a noise perturbation, Z, which is drawn from a distribution, such as a Gaussian distribution. In an alternative embodiment of algorithm 5, the equation utilized in the integration process is given by dX_{τ}=\hat{b}(τ, X_{τ})dτ. The result of the integration process is added to the previous trajectory data,

$${X}_{τ}^{t} ,$$

to create a next state

$${X}_{τ + d τ}^{t} ,$$

which is fed back into the iterative loop, until the target state is reached, at which point

$${X}_{τ = 1}^{t} ,$$

as the target state is returned. It is understood that, while embodiments of the training algorithm are shown above, modifications to the training algorithm contemplated as being within the scope of the invention. For example, one or more of the prediction networks, or their functionality can be altered, or removed. Additionally, the integration step may be altered, to accommodate changes based on the selection of networks.

FIG. 5 illustrates each state in the iterative process 508a . . . 508n from the initial state to the target state, illustrating the process of simulating molecular dynamics, according to the present invention. In embodiments, each of state from start state to the target state, and all next states, are rendered in one or more of: a human-perceptible format, or a machine-perceptible format for use in visualization of all-atom molecular dynamics, as shown at 508a . . . 508n, or for additional processing by one or more computing devices, computational systems, etc. In exemplary embodiments, the human-perceptible format includes, but is not limited to, displaying at a user interface each state, or in any other medium or fashion perceptible by humans. In exemplary embodiments, the machine-perceptible format includes, but is not limited to, an format configured to be interpreted by a machine, such as a computing device, processor, Graphic Processing Unit, etc., and/or any analog or digital format capable of being processed by a machine.

Numerous advantages of the architecture, and operation, of Transport Operator 100 are disclosed above. Additional advantages include, the use of irreducible feature representations in Orthogonal Groups such as O3, and/or, SO3 and the utilization of Euclidean equivariant neural networks rendering Transport Operator 100 SO(3)-equivariant. Equivariance of this kind ensures that outputs transform consistently with inputs under rotation, making Transport Operator 100 more efficient for modeling the rotationally symmetric dynamics of molecular structures in 3D space. Furthermore, the sampling methodology of the present invention, allows Transport operator 100 to directly bridge trajectory snapshots, leveraging the configuration proximity of consecutive timesteps and enabling a transformation that stays close to physical states, thereby improving efficiency by reducing computational expense via utilization of larger timesteps in simulation. This is in contrast to prior approaches that rely on transforming Gaussian priors, via stochastic (SDE) or ordinary differential equations (ODE), where the prior often lies far from the true data distribution.

Various additional aspects, and advantages of the present invention are outlined in, Costa, A. D. S., Mitnikov, I., Pellegrini, F., Daigavane, A., Geiger, M., Cao, Z., . . . & Jacobson, J. (2024). “Equijump: Protein dynamics simulation via so (3)-equivariant stochastic interpolants.” arXiv preprint arXiv:2410.09667 and I, Mitnikov. (2024). “Geometric Deep Learning for Biomolecules” [Master of Engineering in Computation and Cognition, Massachusetts Institute of Technology]. DSpace MIT Libraries, the entire contents of each are hereby incorporated by reference.

Embodiments of the invention and all of the functional operations described in this specification can be implemented in digital electronic circuitry, or in computer software, firmware, or hardware, including the structures disclosed in this specification and their structural equivalents, or in combinations of one or more of them. Embodiments of the invention can be implemented as one or more computer program products, e.g., one or more modules of computer program instructions encoded on a computer readable medium for execution by, or to control the operation of, data processing apparatus. The computer readable medium can be a machine-readable storage device, a non-transitory machine-readable storage device, a machine-readable storage substrate, a memory device, a composition of matter effecting a machine-readable propagated signal, or a combination of one or more of them. The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. A propagated signal is an artificially generated signal, e.g., a machine-generated electrical, optical, or electromagnetic signal that is generated to encode information for transmission to suitable receiver apparatus.

A computer program (also known as a program, software, software application, script, or code) can be written in any form of programming language, including compiled or interpreted languages, and it can be deployed in any form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Generally, a computer will also include a communications device. The communication device can include hardware and/or software for generating and communicating signals over a direct and/or indirect network communication link. As used herein, a direct link can include a link between two devices where information is communicated from one device to the other without passing through an intermediary. For example, the direct link can include a Bluetooth™ connection, a Zigbee connection, a Wifi Direct™ connection, a near-field communications (“NFC”) connection, an infrared connection, a wired universal serial bus (“USB”) connection, an ethernet cable connection, a fiber-optic connection, a firewire connection, a microwire connection, and so forth. In another example, the direct link can include a cable on a bus network. An indirect link can include a link between two or more devices where data can pass through an intermediary, such as a router, before being received by an intended recipient of the data. For example, the indirect link can include a WiFi connection where data is passed through a WiFi router, a cellular network connection where data is passed through a cellular network router, a wired network connection where devices are interconnected through hubs and/or routers, and so forth. The cellular network connection can be implemented according to one or more cellular network standards, including the global system for mobile communications (“GSM”) standard, a code division multiple access (“CDMA”) standard such as the universal mobile telecommunications standard, an orthogonal frequency division multiple access (“OFDMA”) standard such as the long term evolution (“LTE”) standard, and so forth.

Moreover, a computer can be embedded in another device, e.g., a tablet computer, a mobile telephone, a personal digital assistant (PDA), a mobile audio player, a Global Positioning System (GPS) receiver, to name just a few. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, embodiments of the invention can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input.

Embodiments of the invention can be implemented in a computing system that includes a back end component, e.g., as a data server, or that includes a middleware component, e.g., an application server, or that includes a front end component, e.g., a client computer having a graphical user interface or a Web browser through which a user can interact with an implementation of the invention, or any combination of one or more such back end, middleware, or front end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship of client and server arises by virtue of computer programs running on the respective computers and having a client-server relationship to each other.

While this specification contains many specifics, these should not be construed as limitations on the scope of the invention or of what may be claimed, but rather as descriptions of features specific to particular embodiments of the invention. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

It should be understood, of course, that the foregoing relates to exemplary embodiments of the invention and that modifications may be made without departing from the spirit and scope of the invention as set forth in the following claims.

What is claimed is:

1. A computer-implemented method for simulating molecular dynamics, comprising:
a. receiving an initial molecular conformation having at least: an encoded sequence of residue labels, and an encoded representation of a plurality of geometric features;
b. generating, using a conditioner network, a conditioned representation of the initial molecular conformation;
c. iteratively determining a next molecular conformation, comprising:
i. sampling a noise perturbation;
ii. computing, using a plurality of drift networks, a plurality of drift components using the initial molecular configuration, the conditioned representation, and a latent time;
iii. computing, using a plurality of noise networks, a plurality of noise components using the initial molecular configuration, the conditioned representation, and the latent time;
iv. calculating, using an update equation, an update step, wherein the plurality of drift components, the plurality of noise components, and the noise perturbation are inputs to the update equation;
v. calculating the next molecular conformation using the initial molecular conformation and the update step; and
vi. repeating (c), until a target molecular conformation is reached.

2. The computer-implemented method of claim 1, wherein step (c), further comprises:
a. after (v.) calculating the next molecular conformation and before (vi.) repeating (c), rendering the next molecular conformation; and
b. once the target molecular conformation is reached, rendering the target molecular conformation.

3. The computer-implemented method of claim 1, wherein the encoded representation of the plurality of geometric features include at least: a position of first atom, and a plurality of geometric coordinates of one or more additional atoms relative to the position of the first atom.

4. The computer-implemented method of claim 3, wherein the encode representation of the plurality of geometric features is a Tensor cloud, and the plurality of geometric coordinates are irreducible representation in an orthogonal group.

5. The computer-implemented method of claim 1, wherein each of the conditioner network, the plurality of drift networks, and the plurality of noise networks, are deep neural networks, comprising:
one or more stacked blocks, each having:
a self-interaction layer configured to update one or more of the plurality of geometric features; and
a spatial convolution layer configured to aggregate one or more of the plurality of geometric features.

6. The computer-implemented method of claim 5, wherein the deep neural networks are Euclidean equivariant neural networks.

7. The computer-implemented method of claim 5, wherein the deep neural networks are trained on trajectory data using one or more generative models.

8. The computer-implemented of claim 7, wherein the one or more generative models are a stochastic interpolant.

9. The computer-implemented method of claim 1, wherein the update equation is a differential equation.

10. The computer-implemented method of claim 9, wherein the differential equation is one or more of: an ordinary differential equation, or a stochastic differential equation.

11. A non-transitory computer-readable medium comprising instructions for simulating molecular dynamics that, when executed by a processor, cause the processor to:
a. receive an initial molecular conformation having at least: an encoded sequence of residue labels, and an encoded representation of a plurality of geometric features;
b. generate, using a conditioner network, a conditioned representation of the initial molecular conformation;
c. iteratively determine a next molecular conformation, comprising:
i. sample a noise perturbation;
ii. compute, using a plurality of drift networks, a plurality of drift components using the initial molecular configuration, the conditioned representation, and a latent time;
iii. compute, using a plurality of noise networks, a plurality of noise components using the initial molecular configuration, the conditioned representation, and the latent time;
iv. calculate, using an update equation, an update step, wherein the plurality of drift components, the plurality of noise components, and the noise perturbation are inputs to the update equation;
v. calculate the next molecular conformation using the initial molecular conformation and the update step; and
vi. repeat (c), until a target molecular conformation is reached.

12. The non-transitory computer-readable medium of claim 11, wherein step (c), further comprises:
a. after (v.) calculating the next molecular conformation and before (vi.) repeating (c), rendering the next molecular conformation; and
b. once the target molecular conformation is reached, rendering the target molecular conformation.

13. The non-transitory computer-readable medium of claim 11, wherein the encoded representation of the plurality of geometric features include at least: a position of first atom, and a plurality of geometric coordinates of one or more additional atoms relative to the position of the first atom.

14. The non-transitory computer-readable medium of claim 13, wherein the encode representation of the plurality of geometric features is a Tensor cloud, and the plurality of geometric coordinates are irreducible representation in an orthogonal group.

15. The non-transitory computer-readable medium of claim 11, wherein each of the conditioner network, the plurality of drift networks, and the plurality of noise networks, are deep neural networks, comprising:
one or more stacked blocks, each having:
a self-interaction layer configured to update one or more of the plurality of geometric features; and
a spatial convolution layer configured to aggregate one or more of the plurality of geometric features.

16. The non-transitory computer-readable medium of claim 15, wherein the deep neural networks are Euclidean equivariant neural networks.

17. The non-transitory computer-readable medium of claim 16, wherein the deep neural networks are trained on trajectory data using one or more generative models.

18. The non-transitory computer-readable medium of claim 17, wherein the one or more generative models are a stochastic interpolant.

19. The non-transitory computer-readable medium of claim 11, wherein the update equation is a differential equation.

20. The non-transitory computer-readable medium of claim 19, wherein the differential equation is one or more of: an ordinary differential equation, or a stochastic differential equation.

21. A computational system for simulating molecular dynamics, comprising:
at least one processor, and at least one memory, storing instructions that, when executed cause the at least one processor to:
a. receive an initial molecular conformation having at least: an encoded sequence of residue labels, and an encoded representation of a plurality of geometric features;
b. generate, using a conditioner network, a conditioned representation of the initial molecular conformation;
c. iteratively determine a next molecular conformation, comprising:
i. sample a noise perturbation;
ii. compute, using a plurality of drift networks, a plurality of drift components using the initial molecular configuration, the conditioned representation, and a latent time;
iii. compute, using a plurality of noise networks, a plurality of noise components using the initial molecular configuration, the conditioned representation, and the latent time;
iv. calculate, using an update equation, an update step, wherein the plurality of drift components, the plurality of noise components, and the noise perturbation are inputs to the update equation;
v. calculate the next molecular conformation using the initial molecular conformation and the update step; and
vi. repeat (c), until a target molecular conformation is reached.

22. The computational system of claim 21, wherein step (c), further comprises:
a. after (v.) calculating the next molecular conformation and before (vi.) repeating (c), rendering the next molecular conformation; and
b. once the target molecular conformation is reached, rendering the target molecular conformation.

23. The computational system of claim 21, wherein the encoded representation of the plurality of geometric features include at least: a position of first atom, and a plurality of geometric coordinates of one or more additional atoms relative to the position of the first atom.

24. The computational system of claim 23, wherein the encode representation of the plurality of geometric features is a Tensor cloud, and the plurality of geometric coordinates are irreducible representation in an orthogonal group.

25. The computational system of claim 21, wherein each of the conditioner network, the plurality of drift networks, and the plurality of noise networks, are deep neural networks, comprising:
one or more stacked blocks, each having:
a self-interaction layer configured to update one or more of the plurality of geometric features; and
a spatial convolution layer configured to aggregate one or more of the plurality of geometric features.

26. The computational system of claim 25, wherein the deep neural networks are Euclidean equivariant neural networks.

27. The computational system of claim 26, wherein the deep neural networks are trained on trajectory data using one or more generative models.

28. The computational system of claim 27, wherein the one or more generative models are a stochastic interpolant.

29. The computational system of claim 21, wherein the update equation is a differential equation.

30. The computational system of claim 29, wherein the differential equation is one or more of: an ordinary differential equation, or a stochastic differential equation.
